(19) United States
(12) Patent Application Publication
(10) Pub. No.: US 2014/0026941 A1
(43) Pub. Date: Jan. 30, 2014

(54) SOLAR POWER GENERATING APPARATUS

(71) Applicant: SAMSUNG SDI CO., LTD., Yongin-si (KR)

(72) Inventor: Hyun-Chul KIM, Yongin-si (KR)

(73) Assignee: SAMSUNG SDI CO., LTD., Yongin-si, Gyeonggi-do (KR)

(21) Appl. No.: 13/734,119

(22) Filed: Jan. 4, 2013

(30) Foreign Application Priority Data
Jul. 25, 2012 (KR) 10-2012-0081401

(51) Int. Cl. H01L 31/052

(52) U.S. Cl. CPC H01L 31/0522
USPC 136/246

(57) ABSTRACT

A solar power generating apparatus includes a support plate, a solar cell module having a first side and a second side opposite the first side, the first side of the solar cell module being pivotally coupled to the support plate, a guide unit on a rear surface of the solar cell module, and a support unit having a first side and a second side opposite the first side, the first side of the support unit being pivotally coupled to the support plate, and the second side of the support unit being coupled to the guide unit, the second side of the support unit being configured to linearly move along the guide unit to adjust inclination of the solar cell module.

### RELATED APPLICATIONS

This application claims under 35 U.S.C. §119 priority to and the benefit of Korean Patent Application No. 10-2012-0081401, filed on Jul. 25, 2012, in the Korean Intellectual Property Office, and entitled: “Solar Power Generating Apparatus,” the entire contents of which are incorporated herein by reference.

### BACKGROUND

1. Field

One or more embodiments relate to a solar power generating apparatus, and more particularly, to a solar power generating apparatus that maximizes the utilization of an area where a solar cell module is installed.

2. Description of the Related Art

Recently, as existing energy resources, e.g., oil and coal, are expected to be depleted within a few decades, interest in substitutes for the existing energy resources has increased. From among the substitutes, solar cells have been drawing attention as next-generation cells for directly converting solar energy into electrical energy by using a semiconductor device.

Solar cells, which are devices for converting solar energy into electrical energy by using the photovoltaic effect, may be classified into silicon solar cells, thin film solar cells, dye-sensitized solar cells, and organic/polymer solar cells, according to materials. From among the solar cells listed above, the silicon solar cells are the most widely used.

A solar power generating apparatus may be formed by appropriately arranging solar cell modules, in which a plurality of solar cells are connected in series or in parallel. The efficiency of the solar power generating apparatus increases as more solar cells are arranged in a limited space, in which the solar power generating apparatus is installed and sunlight is incident on the solar cell modules at a greater incidence angle.

### SUMMARY

One or more embodiments include a solar power generating apparatus that maximizes the utilization of a space in which a solar cell module is installed.

One or more embodiments also include a solar power generating apparatus whose efficiency is improved by increasing an incidence angle at which sunlight is incident on a solar cell module.

According to one or more embodiments, a solar power generating apparatus may include a support plate, a solar cell module having a first side and a second side opposite the first side, the first side of the solar cell module being pivotally coupled to the support plate, a guide unit on a rear surface of the solar cell module, and a support unit having a first side and a second side opposite the first side, the first side of the support unit being pivotally coupled to the support plate, and the second side of the support unit being coupled to the guide unit, the second side of the support unit being configured to linearly move along the guide unit to adjust inclination of the solar cell module.

An area of an orthogonal projection defined by the solar cell module and the support unit may be constant.

The support plate and the solar cell module may define a first angle that is an acute angle, the support plate and the support unit may define a second angle that is an acute angle, and the first angle and the second angle may increase/decrease oppositely.

An outer surface of the support unit may include a light-reflecting surface.

The light-reflecting surface may include a plurality of ridges and grooves which extend parallel to each other and the ground.

The solar cell module may include: a front substrate; a rear substrate; solar cells that are disposed between the front substrate and the rear substrate; and frame units that are disposed at edges of the front substrate and the rear substrate and couple the front substrate and the rear substrate.

Each of the frame units may include: an upper coupling portion that contacts a top surface of the front substrate; a lower coupling portion that contacts a bottom surface of the rear substrate; a connection coupling portion that connects the upper coupling portion and the lower coupling portion; and a leg portion that extends from the connection coupling portion and has an L-shaped cross-section, wherein the guide unit is formed on the leg portion.

The guide unit may include a guide rail that extends in a long axis direction of the solar cell module, and the support unit includes a rail holder that is disposed on an end portion of the second side of the support unit and is coupled to the guide rail.

The rail holder may be pivotable.

The solar power generating apparatus may further include a rotating unit that is disposed under the support plate.

The rotating unit may include a motor, and a control unit that controls an operation of the motor and an inclination of the solar cell module.

According to another aspect, a solar power generating apparatus includes: a support plate that includes a flat top surface; and a solar cell array that is disposed on the top surface, wherein the solar cell array includes: a plurality of solar cell modules whose one sides are pivotally coupled to the support plate and that are spaced apart from one another; guide units that are formed on rear surfaces of the plurality of solar cell modules; and a plurality of support units whose first sides are pivotally coupled to the support plate and second sides are coupled to the guide units and support the plurality of solar cell modules, wherein the support plate and each of the plurality of solar cell modules form a first angle that is an acute angle, the support plate and each of the plurality of support units form a second angle that is an acute angle, the first angle is adjusted as the second side of each of the plurality of support units linearly moves along each of the guide units, and the first angle and the second angle increase/decrease oppositely.

Areas of orthogonal ridges formed by the plurality of solar cell modules and the plurality of support units may be constant.

Outer surfaces of the plurality of support units may include light-reflecting surfaces.

Each of the light-reflecting surfaces may include a plurality of ridges and grooves which extend parallel to each other and the ground. The light-reflecting surface included in a predetermined support unit from among the plurality of support units may apply reflected light to a solar cell module adjacent to the predetermined support unit from among the plurality of solar cell modules.

Each of the plurality of solar cell modules may include a front surface, a rear surface, solar cells that are disposed between the front surface and the rear surface, and frame units that are disposed at edges of the front surface and the rear surface and couple the front surface and the rear surface, wherein each of the frame units includes an upper coupling portion that contacts a top surface of the front substrate, a lower coupling portion that contacts a bottom surface of the rear substrate, a connection coupling portion that connects the upper coupling portion and the lower coupling portion, and a leg portion that extends from the connection coupling portion and has an L-shaped cross-section, wherein the guide unit is formed on the leg portion.

Each of the guide units may include a guide rail, and each of the plurality of support units may include a rail holder that is coupled to the guide rail, wherein the rail holder is pivotable.

A plurality of the solar cell arrays may be arranged in a direction perpendicular to longitudinal directions of the solar cell arrays.

The solar power generating apparatus may further include a rotating unit that is disposed under the support plates, wherein the support plates are rotated by the rotating unit.

### BRIEF DESCRIPTION OF THE DRAWINGS

Features will become apparent to those of ordinary skill in the art by describing in detail exemplary embodiments with reference to the attached drawings, in which:

FIG. 1 illustrates a perspective view of a solar power generating apparatus according to an embodiment;

FIG. 2 illustrates a cross-sectional view of a solar cell module and a support unit of the solar power generating apparatus of FIG. 1;

FIG. 3 illustrates a cross-sectional view for explaining movements of the solar cell module and the support unit of FIG. 2;

FIG. 4 illustrates a cross-sectional view of the solar cell module and the support unit of the solar power generating apparatus of FIG. 1;

FIGS. 5A through 5C illustrate cross-sectional views for explaining a shape of the solar cell module;

FIG. 6 illustrates a cross-sectional view of two solar cell modules and the support units of the solar power generating apparatus of FIG. 1;

FIG. 7 illustrates an exploded perspective view of the solar cell module of the solar power generating apparatus of FIG. 1; and

FIG. 8 illustrates a perspective view of the support unit of the solar power generating apparatus of FIG. 1.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

As used herein, the term “and/or” includes any and all combinations of one or more of the associated listed items. Expressions such as “at least one of,” when preceding a list of elements, modify the entire list of elements and do not modify the individual elements of the list.

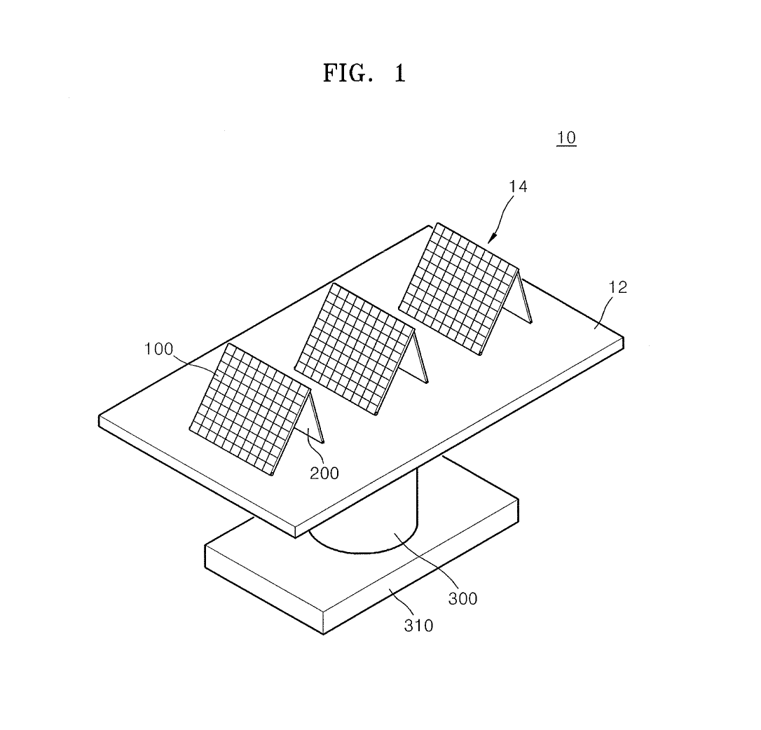

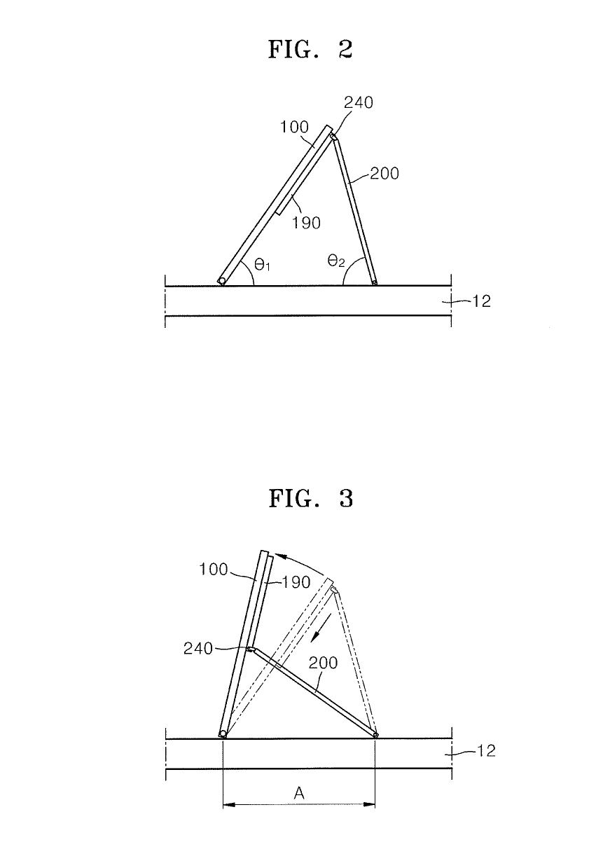

FIG. 1 is a perspective view of a solar power generating apparatus 10 according to an embodiment. FIG. 2 is a cross-sectional view illustrating a solar cell module 100 and a support unit 200 of the solar power generating apparatus 10, and FIG. 3 is a cross-sectional view for explaining movements of the solar cell module 100 and the support unit 200.

Referring to FIGS. 1 and 2, the solar power generating apparatus 10 may include a support plate 12, the solar cell module 100 having one side pivotally coupled to the support plate 12, a guide unit 190 on a rear surface of the solar cell module 100, and the support unit 200 having a first side pivotally coupled to the support plate 12 and a second side coupled to the guide unit 190. Also, the solar power generating apparatus 10 may further include a rotating unit 300 that is disposed under the support plate 12.

The support plate 12 has a flat top surface, and supports a plurality of the solar cell modules 100, e.g., the plurality of the solar cell modules 100 may be aligned on the top surface of the support plate 12 to define a solar cell module array 14. The support plate 12 may be formed of, e.g., a metal, a polymer, or wood. For example, the support plate 12 may have a plate shape, as shown in FIG. 1, or a lattice shape, e.g., a structure having strips of wood or metal crossing each other.

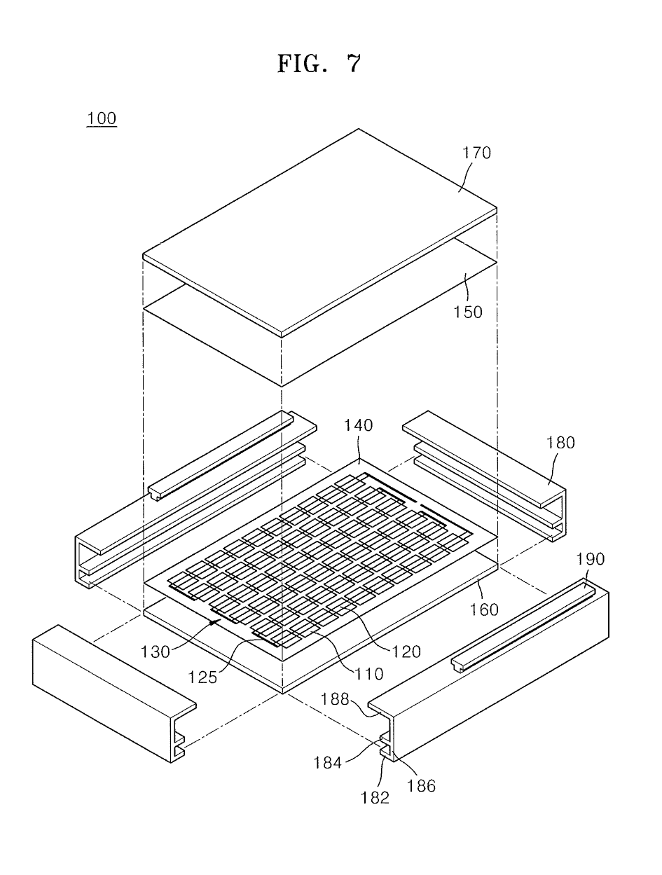

Each of the solar cell modules 100 converts sunlight incident thereon into electrical energy. To this end, the solar cell module 100 includes a plurality of solar cells (not shown). The structure of the solar cell module 100 will be explained in detail below with reference to FIG. 7.

Each of the solar cells in the solar cell module 100 may exhibit maximum efficiency when sunlight is incident on the solar cell at an incidence angle of 90°. However, since the solar power generating apparatus 10 including the plurality of solar cell modules 100 has a limited installation space, an increased number of the solar cell modules 100 in the same installation space of the solar power generating apparatus 10 may increase the overall efficiency of the solar power generating apparatus 10, despite a relatively lower efficiency of each of the solar cell modules 100. In other words, increasing the number of the solar cell modules 100 in a same installation space, i.e., so each solar cell module 100 is positioned to have the sunlight incident thereon at an incidence angle smaller than 90°, may increase an overall efficiency of the solar power generating apparatus 10 despite reduced efficiency of each solar cell modules 100, e.g., as compared to maximum efficiency when sunlight is incident on the solar cell at an incidence angle of 90°. This will be explained in more detail below with reference to Table 1.

Table 1 shows a result obtained by comparing three cases. Case 1 refers to a single solar cell module disposed parallel to the ground, i.e., sunlight is incident thereon at an incidence angle of 90°, Case 2 refers to a single solar cell module non-parallel to the ground, i.e., sunlight is incident thereon at an oblique incidence angle θ, and Case 3 refers to a plurality of solar cell modules that are positioned in a same installation area as Case 1 and at a same angle as Case 2. It is noted that in Table 1, the incidence angle θ is 62°, and the installation area refers to an orthogonal projection of the solar cell module on the ground. It is further noted that the installation area of Case 1 equals the area of the solar cell module, i.e., as the solar cell nodule is parallel to the ground, and is assumed to be 100%, and the installation area of Case 2, i.e., the solar cell module at the oblique angle, equals about 47% of the installation area of Case 1.

TABLE 1

| | Case 1 | Case 2 | Case 3 |
|---|---|---|---|
| Open-Circuit Voltage | 1.38 | 0.785 | 0.785 |
| (V_{oc}) [V] | | | |
| Short-Circuit Current | 0.67 | 0.64 | 0.64 |
| (I_{sc}) [A] | | | |
| Fill Factor (F.F.) | 64 | 71 | 71 |
| Installation area [%] | 100 | 47 | 100 |
| Efficiency | 5.94 | 3.55 | 7.55 |

Referring to Table 1, the efficiency of Case 3 is obtained by assuming that the installation area of Case 2 is increased to correspond to the installation area of Case 1. That is, when the solar cell module of Case 2, i.e., with the installation area of 47% of the installation area of Case 1, is installed in an area corresponding to the installation area of Case 1, the efficiency of Case 2 may be increased by as much as an increment in the installation area. In other words, due to the inclination of the solar cell module of Case 2, more solar cell modules may fit into a same limited space, e.g., an area occupied by a single flat solar cell module may fit at least two solar cell modules inclined at 62°. Accordingly, when a plurality of inclined solar cell modules is installed in a same installation area, i.e., Case 3, the overall efficiency of the solar power generating apparatus 10 may be improved.

Referring back to FIG. 2, the guide unit 190 is formed on the rear surface of each of the solar cell modules 100, i.e., on a surface opposite to that on which sunlight is incident, and may extend in one direction of the solar cell module 100, e.g., the guide unit 190 may extend along at least half of each solar cell module 100 along a longitudinal direction of the solar cell module. The one direction of the solar cell module 100 may be a long axis direction of the solar cell module 100 when the solar cell module 100 has a rectangular shape. The guide unit 190 is coupled to the support unit 200. The guide unit 190 may be a guide rail, but the present embodiment is not limited thereto and the guide unit 190 may include a guide groove. The guide unit 190 guides a linear movement of the support unit 200 that is coupled to the guide unit 190, as will be explained in more detail below.

The first side of the support unit 200 may be pivotally coupled to the support plate 12, so the first side of the support unit 200 may be rotatable to allow movement of the support unit 200 around the first side. The second side of the support unit 200 may be coupled to the guide unit 190 that is formed on the rear surface of the solar cell module 100, and may supports the solar cell module 100, e.g., the solar cell module 100 may lean on the support unit 200. The support unit 200 may be formed of, e.g., a metal or plastic material having high processability, and may include a rail holder 240 that is disposed on an end portion of the second side of the support unit 200. The rail holder 240 may be coupled to the guide unit 190.

The solar cell module 100, the support unit 200, and the support plate 12 may define a triangular shape. That is, the solar cell module 100 and the support plate 12 may form a first angle θ₁ therebetween, i.e., an acute angle, and the support unit 200 and the support plate 12 may define a second angle θ₂ therebetween, i.e., an acute angle. The solar cell module 100 having a predetermined inclination may be stably supported, and more solar cell modules 100 may be installed in a limited installation space. Therefore, utilization of the limited installation space and the efficiency of the solar power generating apparatus 10 may be improved.

Since the solar cell module 100 is pivotally coupled to the support plate 12, the inclination of the solar cell module 100 may be adjusted according to an incidence angle of the sunlight. In other words, the inclination of the solar cell module 100, i.e., the first angle θ₁, may be adjusted according to the sunlight in order to optimize the incidence angle of the sunlight on the solar cell module 100 by moving the second side of the support unit 200 along the guide unit 190, as shown in FIG. 3.

In detail, as the first side of the support unit 200 is pivotally attached to the support plate 12, the support unit 200 may move linearly along the guide unit 190. The movement of the support unit 200 along the guide unit 190 may change the contact position of the support unit 200 with the solar cell module 100, thereby enabling movement of the solar cell module 100.

For example, when the rail holder 240 moves to a lower portion of the solar cell module 100 along the guide unit 190, i.e., when the rail holder 240 of the support unit 200 slides down the guide unit 190 toward the support plate 12, the solar cell module 100 is pushed back by the support unit 200, thereby increasing the inclination angle of the solar cell module 100 and decreasing the inclination angle of the support unit 200. That is, the second angle θ₂ formed between the support unit 200 and the support plate 12 in FIG. 2 is reduced, while the first angle θ₁ formed between the solar cell module 100 and the support plate 12 is increased. In other words, when the inclination of the support unit 200 is reduced, the rail holder 240 may move downward along the guide unit 190 and the inclination of the solar cell module 100 may be increased.

In another example, when the rail holder 240 moves to an upper portion of the solar cell module 100 along the guide unit 190, the inclination of the support unit 200 is increased. Accordingly, the solar cell module 100 leans toward the support guide 200, and the inclination of the solar cell module 100 is reduced. That is, the first angle θ₁ formed between the solar cell module 100 and the support plate 12 is reduced. In other words, when the inclination of the support unit 200 is increased, the rail holder 240 may move upward along the guide unit 190 and the inclination of the solar cell module 100 may be reduced.

Accordingly, since the inclination of the solar cell module 100 may be adjusted in accordance with the sun position, i.e., to optimize incidence of sunlight thereon, the efficiency of the solar cell module 100 may be improved.

The first angle θ₁ between the solar cell module 100 and the support plate 12, and the second angle θ₂ between the support unit 200 and the support plate 12 may increase/decrease oppositely, i.e., have an inverse relationship. Even when the second angle θ₂ between the support unit 200 and the support plate 12 and the first angle θ₁ between the solar cell module 100 and the support plate 12 are changed, an area A, i.e., an orthogonal projection formed by the solar cell module 100 and the support unit 200 as illustrated in FIG. 3, is maintained constant. Accordingly, an additional apparatus or an additional space for changing the inclination of the solar cell module 100 is not necessary.

Referring back to FIG. 1, the solar power generating apparatus 10 may further include the rotating unit 300 that is disposed under the support plate 12. The rotating unit 300 may be provided on a fixed plate 310. The rotating unit 300 may include a motor, and a control unit that controls an operation of the motor and an inclination of the solar cell module 100. Also, the rotating unit 300 may change a direction of the solar cell module 100 by rotating the support plate 12.

Accordingly, according to the present embodiment, since more solar cell modules 100 may be stably installed and inclinations and directions of the installed solar cell modules 100 may be adjusted, the efficiency of the solar power generating apparatus 10 may be improved.

Although not shown in FIG. 1, a plurality of the solar cell module arrays 14 may be provided in a direction perpendicular to a longitudinal direction of the solar cell module array 14.

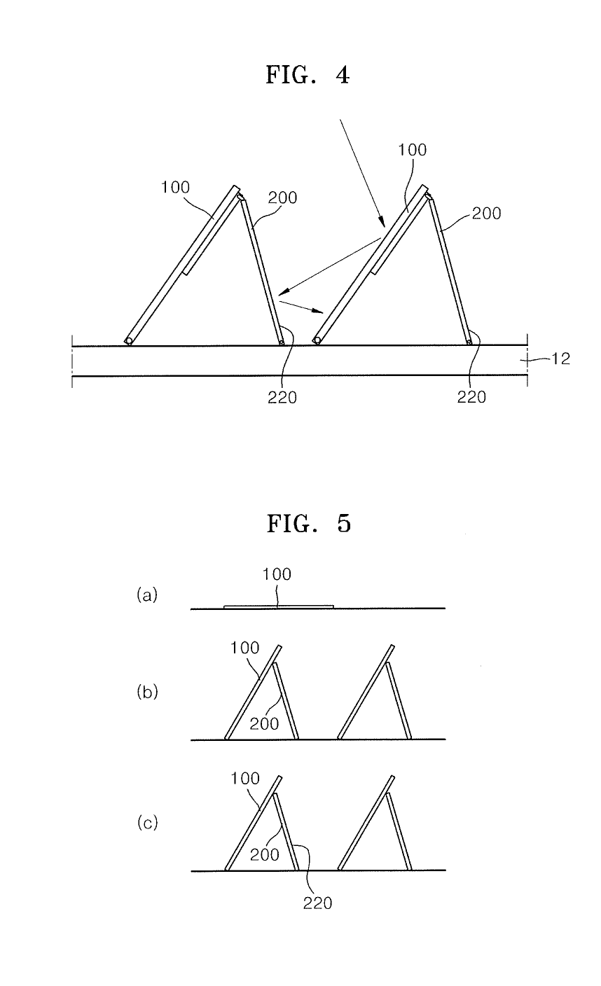

FIG. 4 is a cross-sectional view illustrating a plurality of the solar cell modules 100 and the support units 200 of the solar power generating apparatus 10. FIGS. 5A through 5C are cross-sectional views for explaining the shape of the solar cell module 100.

Referring to FIG. 4, two adjacent solar cell modules 100 from among the plurality of solar cell modules 100, and the support units 200 that support the two adjacent solar cell modules 100 are illustrated. An outer surface of each of the support units 200 may include a light-reflecting surface 220.

When sunlight incident on the two adjacent solar cell modules 100 is reflected by the solar cell modules 100, the light-reflecting surfaces 220 may reflect the reflected light again to the solar cell modules 100. Each of the light-reflecting surfaces 220 may be formed by forming a metal layer having a high reflectance, e.g., aluminum or silver, on each of the outer surfaces of the support units 200. For example, the light-reflecting surface 220 may be formed of aluminum having a reflectance equal to or greater than about 80% at all wavelengths.

FIG. 5A illustrates a case where the solar cell module 100 is disposed parallel to the ground, i.e., like Case 1 of Table 1, and FIGS. 5B and 5C illustrate a case where the solar cell module 100 and the support unit 200 form a triangular shape. In FIG. 5C, the solar cell module 100 differs from FIG. 5B by including a light-reflecting surface 220 on the outer surface of the support unit 200 of the solar cell module 100. That is, FIG. 5A illustrates Case 1 of Table 1 and FIG. 5B illustrates Case 2 of Table 1.

Table 2 shows a result obtained by comparing efficiencies of the solar cell modules 100 in FIGS. 5A through 5C.

TABLE 2

| | (a) | (b) | (c) | (d) |
|---|---|---|---|---|
| Open-Circuit | 1.38 | 0.785 | 0.97 | 0.97 |
| Voltage (V_{oc}) [V] | | | | |
| Short-Circuit | 0.67 | 0.64 | 0.64 | 0.64 |
| Current (I_{sc}) [A] | | | | |
| Fill Factor (F.F.) | 64 | 71 | 69 | 69 |
| Installation area [%] | 100 | 47 | 47 | 100 |
| Efficiency | 5.94 | 3.55 | 4.23 | 9.01 |

Columns (a) and (b) of Table 2 represent Cases 1 and 2 of Table 1, respectively. As described with reference to Table 1, when the solar cell module 100 is installed to have a predetermined inclination, more solar cell modules 100 may be installed in the same installation area. Therefore, the overall efficiency of the solar power generating apparatus 10 may be improved.

Column (c) of Table 2 represents a case where a plurality of solar cell modules 100, e.g., two adjacent solar cell modules 100, are coated with the light-reflecting surface 220, as discussed previously with reference to FIG. 4. Further, column (d) of Table 2 refers the plurality of solar cell modules 100 of column (c) installed in an installation area corresponding to the installation area of column (a) of Table 2.

When the efficiency of (d) of Table 2 is compared with that of Case 3 of Table 1, the efficiency in (d), i.e., of the solar cell modules 100 with the light-reflecting surface 220, is higher by about 19% than the efficiency in Case 3, i.e., without the light-reflecting surface 220. In other words, it is found that when the light-reflecting surface 220 is formed on the support unit 200, the overall efficiency of the solar power generating apparatus 10 may be further improved.

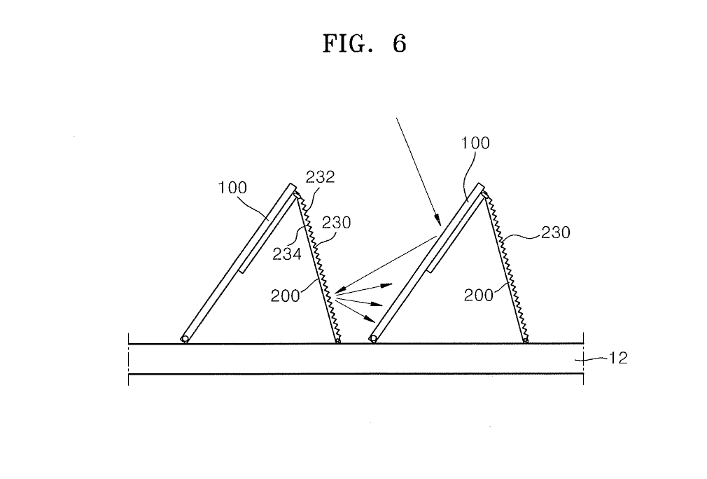

FIG. 6 is a cross-sectional view illustrating two solar cell modules 100, the support units 200 that respectively support the solar cell modules 100, and light-reflecting surfaces 230 that are formed on the outer surfaces of the support units 200.

Referring to FIG. 6, each of the light-reflecting surfaces 230 includes a plurality of ridges 232 and a plurality of grooves 234. The plurality of ridges 232 and the plurality of grooves 234 extend parallel to each other and the ground. When each of the light-reflecting surfaces 230 includes the plurality of ridges 232 and the plurality of grooves 234, and when light reflected by the adjacent solar cell modules 100 are reflected by the light-reflecting surfaces 230 again, irregular reflection occurs. Therefore, light may be re-incident on the adjacent solar cell modules 100 more uniformly.

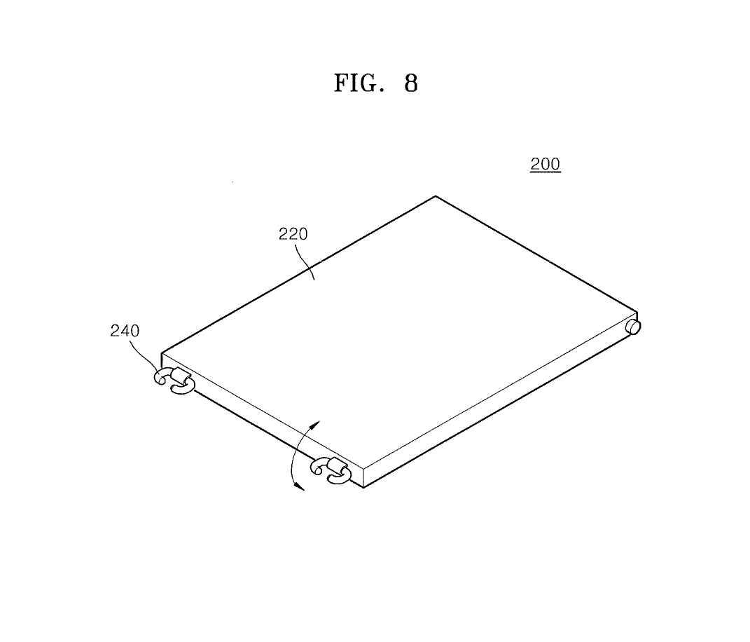

FIG. 7 is an exploded perspective view illustrating the solar cell module 100 of the solar power generating apparatus 10 of FIG. 1. FIG. 8 is a perspective view illustrating the support unit 200 of the solar power generating apparatus 10 of FIG. 1.

Referring to FIG. 7, the solar cell module 100 may include a plurality of solar cells 110, a ribbon 120 that forms a solar cell string 130 by electrically connecting the plurality of solar cells 110, a first sealing film 140 and a front substrate 160 that are disposed over the plurality of solar cells 110, and a second sealing film 150 and a rear substrate 170 that are disposed under the plurality of solar cells 110.

Examples of the solar cells 110, which are semiconductor devices for converting solar energy into electrical energy, may include silicon solar cells, compound semiconductor solar cells, dye-sensitized solar cells, and tandem solar cells.

The ribbon 120 forms the solar cell string 130 by electrically connecting the plurality of solar cells 110 in series or in parallel. In detail, the ribbon 120 may connect a front electrode formed on a light-receiving surface of each of the solar cells 110 and a rear electrode formed on a rear surface of an adjacent solar cell 110 by using a tabbing process. The tabbing process may involve applying a flux to one surface of the solar cell 110, locating the ribbon 120 on the solar cell 110 to which the flux is applied, and performing sintering. Alternatively, the plurality of solar cells 110 may be connected in series or in parallel by attaching conductive films (not shown) between one of the surfaces of the solar cells 110 and the ribbon 120 and then performing thermo-compression.

A plurality of the solar cell strings 130 may be electrically connected by bus ribbons 125. In detail, the bus ribbons 125 may be horizontally disposed on both ends of the solar cell strings 130 that are disposed in a plurality of columns, and may alternately connect both ends of the ribbons 120 of the solar cell strings 130. Although not shown in FIG. 7, the bus ribbons 125 are connected to a junction box (not shown) that is disposed on a rear surface of the solar cell module 100.

The first sealing film 140 is disposed on light-receiving surfaces of the solar cells 110, and the second sealing film 150 is disposed on rear surfaces of the solar cells 110. The first sealing film 140 and the second sealing film 150 are attached by using lamination, and block moisture or oxygen which may badly affect the solar cells 110.

Each of the first sealing film 140 and the second sealing film 150 may be formed of ethylene vinyl acetate (EVA), polyvinyl butyral, silicon resin, ester-based resin, or olefin-based resin.

The front substrate 160 may be disposed on the first sealing film 140, and may be formed of a glass or polymer material having a high light transmittance. Also, in order to protect the solar cells 110 from external impact, the front substrate 160 may be formed of tempered glass, and in order to prevent reflection of sunlight and increase a transmittance of sunlight, the front substrate 160 may be formed of low-iron tempered glass.

The rear substrate 170 for protecting the solar cells 110 at the rear surfaces of the solar cells 110 may have waterproof, insulating, and ultraviolet (UV) light blocking functions, and may be formed by stacking, but not limited to, a polyvinyl fluoride layer, a polyethylene terephthalate (PET) layer, and polyvinyl fluoride layer.

Frame units 180 are disposed at edges of the front substrate 160 and the rear substrate 170 and couple the front substrate 160 and the rear substrate 170. In detail, each of the frame units 180 may include an upper coupling portion 182 that contacts a top surface of the front substrate 160, a lower coupling portion 184 that contacts a bottom surface of the rear substrate 170, a connection coupling portion 186 that connects the upper coupling portion 182 and the lower coupling portion 184, and a leg portion 188 that extends from the connection coupling portion 186 and has an L-shaped cross-section.

The guide unit 190 may be formed on the leg portion 188. In detail, the guide unit 190 may be a guide rail that extends in one direction of the solar cell module 100 and is formed on each of the frame units 180 disposed on both side portions of the solar cell module 100.

Referring to FIG. 8, the support unit 200 may include a rail holder 240 that is coupled to the guide unit 190. As the rail holder 240 is coupled to the guide unit 190 and linearly move along the guide unit 190, inclinations of the support unit 200 and the solar cell module 100 may be changed. Also, the rail holder 240 may be pivotally formed in order to achieve a desired movement and prevent damage according to the movement.

Also, the light-reflecting surface 220 may be formed on the outer surface of the support unit 200 as described above. The light-reflecting surface 220 supplies reflected light to the solar cell module 100 adjacent to the solar cell module 100 supported by the support unit 200. Also, the light-reflecting surface 220 may include a plurality of ridges and grooves as shown in FIG. 6.

As described above, according to the one or more of the above embodiments, a plurality of solar cell modules may be installed in a limited space where a solar power generating apparatus is installed, so utilization of the limited space is improved. Also, since an inclination and a direction of a solar cell module may be changed, the efficiency of the solar power generating apparatus is improved by increasing an incidence angle of the sunlight.

The embodiments of the solar power generating apparatus are not limited in terms of configurations and methods, and the embodiments may be modified by selectively combining all or some of the embodiments.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the inventive concept as set forth in the following claims.

What is claimed is:

1. A solar power generating apparatus, comprising:
a support plate;
a solar cell module having a first side and a second side opposite the first side, the first side of the solar cell module being pivotally coupled to the support plate;
a guide unit on a rear surface of the solar cell module; and
a support unit having a first side and a second side opposite the first side, the first side of the support unit being pivotally coupled to the support plate, and the second side of the support unit being coupled to the guide unit, the second side of the support unit being configured to linearly move along the guide unit to adjust inclination of the solar cell module.

2. The solar power generating apparatus as claimed in claim 1, wherein an area of an orthogonal projection defined by the solar cell module and the support unit is constant.

3. The solar power generating apparatus as claimed in claim 1, wherein the support plate and the solar cell module define a first acute angle, the support plate and the support unit define a second acute angle, and the first acute angle and the second acute angle increase/decrease oppositely.

4. The solar power generating apparatus as claimed in claim 1, wherein an outer surface of the support unit includes a light-reflecting surface.

5. The solar power generating apparatus as claimed in claim 4, wherein the light-reflecting surface includes a plurality of ridges and grooves parallel to each other and to the ground.

6. The solar power generating apparatus as claimed in claim 1, wherein the solar cell module includes:
a front substrate;
a rear substrate;
solar cells between the front substrate and the rear substrate; and
frame units at edges of the front substrate and the rear substrate, each frame unit coupling the front substrate and the rear substrate.

7. The solar power generating apparatus as claimed in claim 6, wherein each of the frame units includes:
an upper coupling portion contacting a top surface of the front substrate;
a lower coupling portion contacting a bottom surface of the rear substrate;
a connection coupling portion connecting the upper coupling portion and the lower coupling portion; and
a leg portion that extends from the connection coupling portion and has an L-shaped cross-section, the guide unit being positioned on the leg portion.

8. The solar power generating apparatus as claimed in claim 1, wherein the guide unit includes a guide rail along a longitudinal direction of the solar cell module, the support unit including a rail holder on the second side of the support unit and coupled to the guide rail.

9. The solar power generating apparatus as claimed in claim 8, wherein the rail holder is pivotable.

10. The solar power generating apparatus as claimed in claim 1, further comprising a rotating unit under the support plate.

11. The solar power generating apparatus as claimed in claim 10, wherein the rotating unit includes a motor, and a control unit that controls an operation of the motor and an inclination of the solar cell module.

12. A solar power generating apparatus, comprising:
a support plate with a flat top surface; and
a solar cell array on the top surface of the support plate, the solar cell array including:
a plurality of solar cell modules having first sides and second sides opposite the first sides, the first sides being pivotally coupled to the support plate and being spaced apart from one another,
guide units on rear surfaces of the plurality of solar cell modules, and
a plurality of support units having first sides and second sides opposite the first sides, the first side of the support unit being pivotally coupled to the support plate, and second sides of the support unit being coupled to the guide units and being configured to support the plurality of solar cell modules,
wherein the support plate and each of the plurality of solar cell modules define a first acute angle, the support plate and each of the plurality of support units define a second acute angle, the first angle being adjusted as the second side of each of the plurality of support units linearly moves along each of the guide units, and the first angle and the second angle increases/decreases oppositely.

13. The solar power generating apparatus as claimed in claim 12, wherein areas of orthogonal projections defined by the solar cell modules and the support units are constant.

14. The solar power generating apparatus as claimed in claim 12, wherein outer surfaces of the plurality of support units include light-reflecting surfaces.

15. The solar power generating apparatus as claimed in claim 14, wherein each of the light-reflecting surfaces includes a plurality of ridges and grooves parallel to each other and to the ground.

16. The solar power generating apparatus as claimed in claim 14, wherein the light-reflecting surface of a predetermined support unit from among the plurality of support units is configured to reflect light to a solar cell module adjacent to the predetermined support unit from among the plurality of solar cell modules.

17. The solar power generating apparatus as claimed in claim 12, wherein each of the plurality of solar cell modules includes:
solar cells between a front surface and a rear surface; and
frame units at edges of the front surface and the rear surface, the frame units coupling the front surface and the rear surface,
wherein each of the frame units includes an upper coupling portion that contacts a top surface of the front substrate, a lower coupling portion that contacts a bottom surface of the rear substrate, a connection coupling portion that connects the upper coupling portion and the lower coupling portion, and a leg portion that extends from the connection coupling portion and has an L-shaped cross-section, the guide unit being formed on the leg portion.

18. The solar power generating apparatus as claimed in claim 12, wherein each of the guide units includes a guide rail, each of the plurality of support units includes a rail holder coupled to the guide rail, and the rail holder being pivotable.

19. The solar power generating apparatus as claimed in claim 12, wherein a plurality of the solar cell arrays are arranged in a direction perpendicular to longitudinal directions of the solar cell arrays.

20. The solar power generating apparatus as claimed in claim 12, further comprising a rotating unit under the support plates, the support plates being configured to be rotated by the rotating unit.
